(19) United States
(12) Patent Application Publication
(10) Pub. No.: US 2007/0068795 A1
(43) Pub. Date: Mar. 29, 2007

(54) Hollow body plasma uniformity adjustment device and method

(76) Inventor: Jozef Brcka, Loundonville, NY (US)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 11/235,593

(22) Filed: Sep. 26, 2005

(51) Int. Cl. C23C 14/32; C23C 14/00

(52) U.S. Cl. 204/192.1; 204/298.01

(57) ABSTRACT

The uniformity of a plasma distribution having a tendency to peak toward the axis of a processing chamber is improved by positioning a hollow body on the chamber axis with an open end facing the processing space. The hollow body controls the distribution of the plasma away from the center and allows plasma at the center. The geometry of the hollow body can be optimized to render the plasma uniform for given conditions. In combined deposition and etch processes, such as simultaneous and sequential etch and iPVD processes, the hollow body provides for a uniform plasma for etching while allowing deposition parameters to be optimized for deposition.

This invention relates to the control of plasma etch process uniformity in an ionized physical vapor deposition (iPVD) processing of semiconductor wafers, and, in general, to metallization plasma processing in semiconductor technology. This invention more particularly relates to processes that combine iPVD and etch processing.

### BACKGROUND OF THE INVENTION

Ionized PVD has been utilized in semiconductor processing for metallization and interconnects and shows promise for extending processing to submicron technology. In the metallization of high aspect ratio (HAR) via holes and trenches on semiconductor wafers, barrier layers and seed layers must provide good sidewall and bottom coverage across the wafer. Ionized PVD is used for barrier and seed layer metallization in advanced IC wafers. Ionized PVD provides good sidewall and bottom coverage in via and trench structures. However, the ionized deposition requirements become more critical as the geometries shrink and as the via dimensions are further reduced below 0.15 micrometers. In such applications, it is highly desirable to have an ionized PVD process where bottom coverage and sidewall coverage are well balanced and overhang is minimized.

The Metallization process may use an ionized physical vapor deposition (iPVD) apparatus having the features described in U.S. Pat. Nos. 6,080,287, 6,132,564, 6,197,165, 6,287,435 and 6,719,886 which patents are hereby expressly incorporated by reference herein. The processing apparatus described in these patents are particularly well suited for sequential or simultaneous deposition and etching. The sequential deposition and etching process can be applied to a substrate in the same process chamber without breaking vacuum or moving the wafer from chamber to chamber. Sequential deposition and etching processes are described in U.S. Pat. No. 6,755,945, hereby expressly incorporated by reference herein. The configuration of the apparatus allows rapid change from ionized PVD deposition mode to etching mode or from etching mode to ionized PVD deposition mode. The configuration of the apparatus also allows for simultaneous optimization of ionized PVD process control parameters during deposition mode and etching process control parameters during etching mode. The consequence of these advantages is a high throughput of wafers with superior via metallization and subsequent electroplated fill operation.

Notwithstanding the advantages of ionized PVD, there are still some constraints to using iPVD at the maximum of its performance. For example, existing hardware does not allow for simultaneous optimizing of the uniformity in both deposition and etching over a wide process window, specifically a wide pressure range. An annular target provides excellent flat field deposition uniformity, but geometrically is limited to the use of large area inductively coupled plasmas (ICP) to generate large size low-pressure plasma for uniform etch processes. An axially situated ICP source is optimal to ionize metal vapor sputtered from the target and fill features in the center of the wafer, but such a source generates an axially peaked high-density plasma profile that does not provide uniform etch in a sequential deposition-etch process or no net deposition process (NND).

The etch portion of a combined deposition-etch process occurs at increased bias at the wafer so deposited metal, typically TaN/Ta for adhesion and barrier properties or Cu for a seed layer, is removed from the flat field areas, namely the horizontal surfaces like the top and bottom planes of a feature, but remains deposited at the sidewalls of the features. The process requires fully identical non-uniformity distributions of the etch and deposition processes, or highly uniform processes.

### SUMMARY OF THE INVENTION

An objective of the present invention is to generate and adjust plasma so as to contribute to the uniform plasma processing in simultaneous and sequential processes that combine deposition and etching. One particular objective of the invention is to provide uniform plasma processing for high aspect ratio feature coverage by ionized PVD, particularly for large diameter wafers, for example, 300 millimeter (mm) wafers.

The present invention provides for the production of a plasma by a large electrode, a ring-shape antenna in the preferred embodiment, and for the adjusting of the plasma density profile by use of an axially positioned device having hollow-body geometry. The device is provided in the vacuum space of the plasma source into which the energy is coupled. The device geometry, including its dimensions and shape, and its placement in the chamber may be optimized for the particular chamber geometry and process pressure range.

These and other objects and advantages of the present invention will be more readily apparent from the following detailed description of illustrated embodiments of the invention.

### BRIEF DESCRIPTION OF THE DRAWINGS

FIG. 1 is a sectional view of an iPVD system for use with the present invention.

FIG. 2 are graphs of plasma density showing the radial dependence of the ion density with and without the plasma adjusting device of the present invention.

FIG. 3 is a cross-sectional view of one embodiment in an iPVD chamber of the type shown in FIG. 1 with a plasma adjusting device according to principles of the present invention.

FIGS. 3A and 3B are perspective and cross-sectional views, respectively, of the hollow body of the embodiment of FIG. 3.

FIG. 4 are normalized forms of the graphs of FIG. 2.

FIG. 5 is a graph showing uniformity of the ion density as a function of the height of the plasma adjusting device two radii R=40 mm and R=70 mm.

FIGS. 6A-6C are two dimensional plots of lines of equal ion density in an iPVD chamber in which:

FIG. 6A shows the peaked plasma in a baseline chamber with a central ICP source as in FIG. 1;

FIG. 6B shows a chamber such as in FIG. 1, but with an enlarged diameter ICP source without a plasma adjusting device and ring-shaped plasma source according to the present invention; and

FIG. 6C shows a chamber similar to FIG. 3 with a plasma adjusting device provided according to principles of the present invention.

FIGS. 7A-B are elevational views, respectively, of conical and spherical plasma adjusting devices according to other embodiments of the present invention.

### DETAILED DESCRIPTION

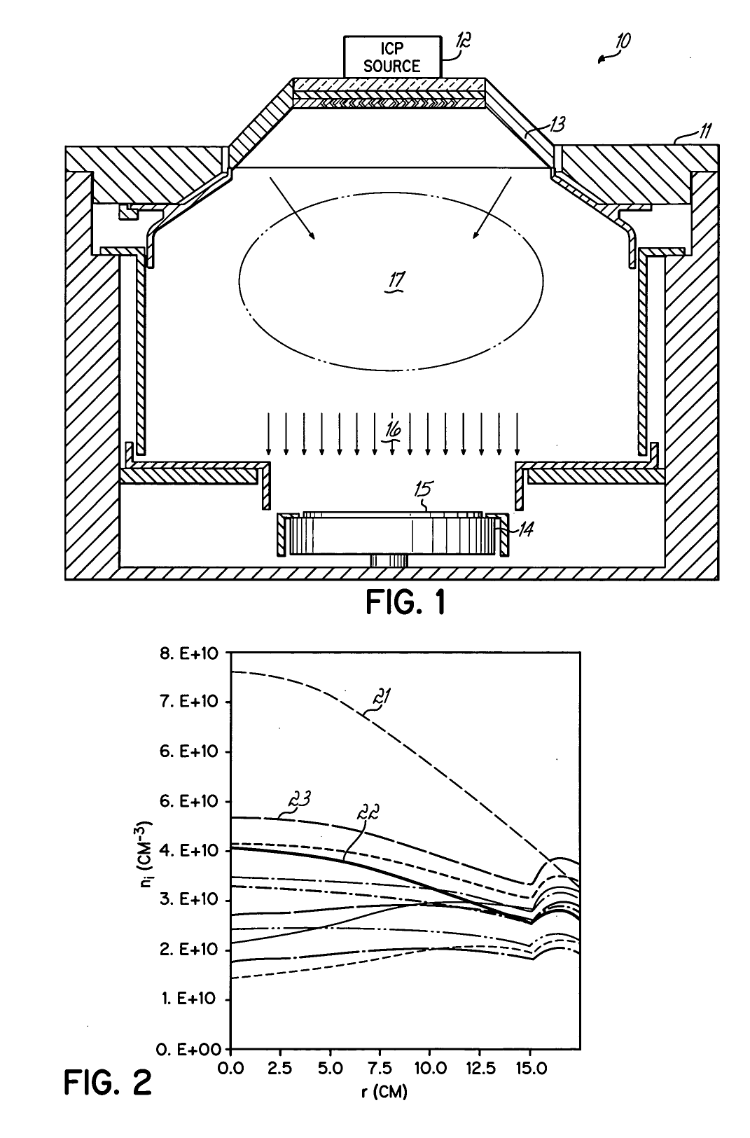

Embodiments of the present invention are described in the context of the apparatus 10 of FIG. 1, even though applicable to other types of systems. The apparatus has features similar to those described in U.S. Pat. Nos. 6,080,287, 6,287,435 and 6,719,886 referred to above.

A typical iPVD system 10, as illustrated in FIG. 1, may include a vacuum chamber 11, an ICP source 12, a metal source 13, and wafer holder 14 on which is supported a wafer 15 for processing, with a processing space 16 through which the sources 12 and 13 and the wafer 15 interact. Energy is coupled from the plasma source 12 into the processing space 16 to form a plasma 17. In iPVD, metal is sputtered from the metal source 13 into the plasma 17 in the space 16, where it is ionized for deposition onto the wafer 15. When the plasma source 12 is an ICP source, RF energy is inductively coupled into the plasma 17.

While plasma processing systems are designed with maximum care and computer simulation, in many cases only a real process performed with a real plasma will reveal the impact of some hardware components of a processing chamber and their interaction with the plasma. Typically, this impact concerns the uniformity of the processing at the wafer. For example, non-uniformity in processing can be generated when changing processing conditions, for example, by interaction of a static magnetic field from a metal source, from inductively coupled plasma (ICP) antenna geometry, and from the simultaneous combination of different plasma processes within the chamber.

Existing iPVD systems, such as those described in U.S. Pat. Nos. 6,080,287, 6,287,435 and 6,719,886, for example, have an on-axis ICP source which produces a strongly peaked plasma density. Such a plasma can provide excellent ionization of the metal sputtered from a target and the subsequent transport of the sputtered metal to a wafer.

Such an iPVD system 10 exhibits a plasma density profile 21 that is peaked at the center, as illustrated in FIG. 2. The profile 21 represents zero table bias on the substrate holder 14, where a table bias of 800 watts results in a similarly shaped but less peaked profile 22. Flattening of the plasma profile can be achieved by reduction of the chamber height, to produce a profile such as the profile 23. However, more significant reduction of chamber height would require radical changes in overall iPVD hardware. The plasma distribution typically does not markedly affect deposition uniformity with iPVD when performed in thermalized metal plasmas and at higher pressure, above 30-50 mTorr. But when performing an etch process at a lower pressure, etch state uniformity can be affected. Etch processes might be typically performed at pressures in the 1 to 10 mTorr range, for example.

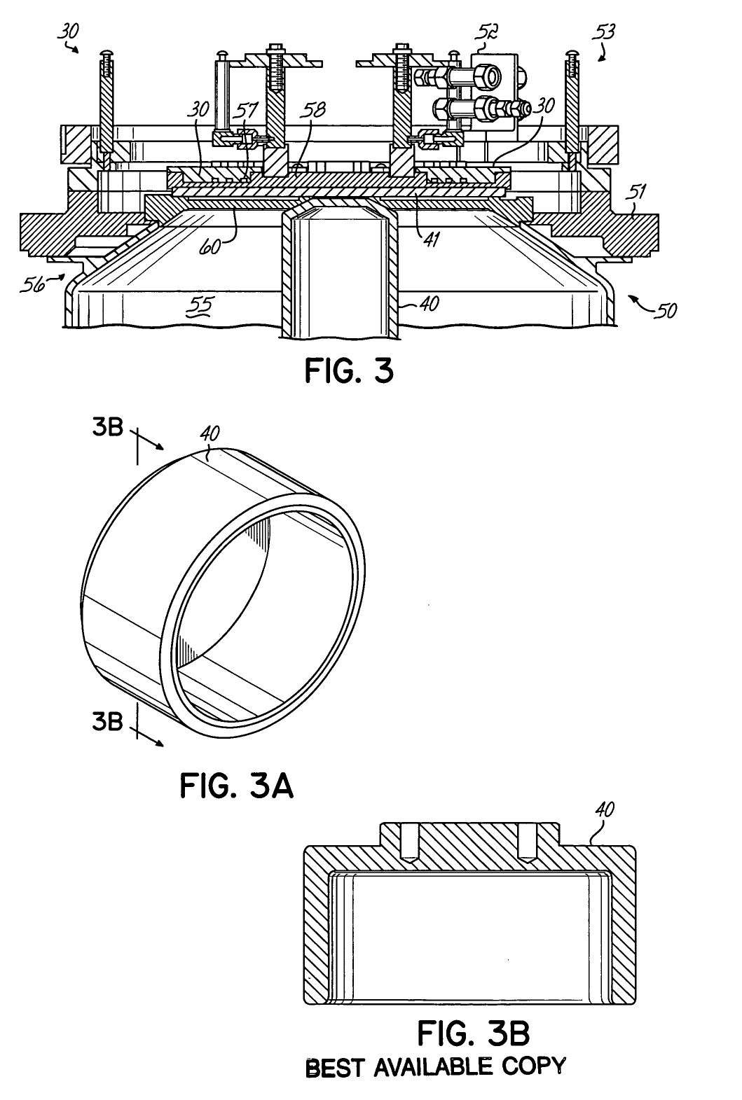

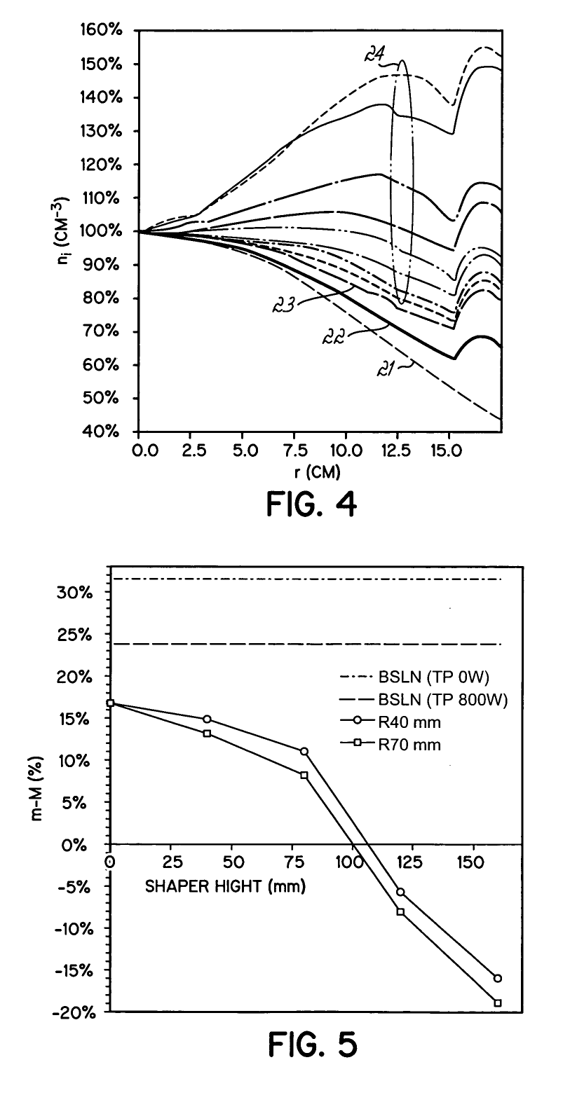

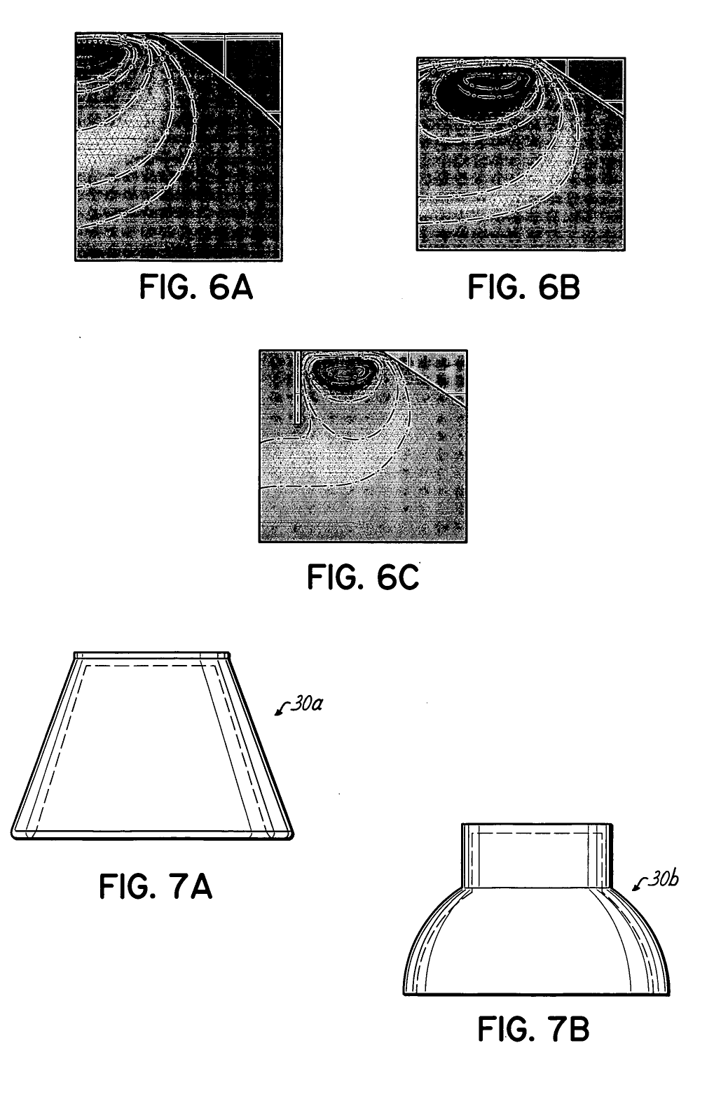

In accordance with certain principles of the present invention, to solve etch rate uniformity problems with minimal impact on the deposition process, an iPVD system 50 is provided in which the center ICP source 12 of FIG. 1 is replaced by a ring-like source 30. The ring-shaped source 30 surrounds a concentric hollow body device 40, which is placed in position below deposition shield 60 inside of a dielectric portion of the chamber wall such as a dielectric window 41 behind which is positioned the antenna of the ring-shaped source 30. FIGS. 2 and 4 are comparative illustrations of density profiles, showing a transition from a center-peaked to a dished ion density profile with increasing radial or axial dimensions of the hollow body plasma adjusting device 40. The graphs of FIG. 4 are normalized forms of the curves of FIG. 2 and also include curves 24 that show the lateral and vertical dimensions of the hollow device 40 have an effect on the plasma density profile. FIG. 4 shows plasma density profiles for various dimensions of the hollow device. Extended surfaces of the hollow device 40 affects recombination of the plasma by impeding ionization in the bulk plasma in the central area of the processing space 16 within the chamber 11. The plasma density profile changes from the domed shape illustrated by curves 21-23 in FIG. 4 to a more dish shape as illustrated by curves 24 in FIG. 4. Dependence of the shape and dimensions of the device 40 affect the distribution of the plasma, as illustrated at different radii in FIG. 5. One example of an embodiment is shown in FIGS. 3A and 3B. Accordingly, while some improvement in plasma uniformity can be gained by reduced chamber height, substantial uniformity improvement can be achieved utilizing a hollow plasma shaping device 40.

More specifically, in the embodiment illustrated in FIG. 3, processing system 50 has a top portion 53 that includes the top ring-like ICP source 52, which includes the ring-shaped antenna 30, and the RF biased substrate holder 14 at the bottom of a chamber 51 connected through a matching network (not shown) to RF generator (not shown). A process space 55 is enclosed by the vacuum chamber 51 and includes a metal source 56. The ring-shaped plasma source 30 includes an inductive antenna 57, which is separated from the processing space 55 by a TEFLON spacer 58 and a dielectric window 41 in the wall of the chamber 51, which is protected by a deposition shield 60 having radial slots (not shown). The hollow device 40 is positioned below, or toward the processing space 50 from, the deposition shield 60.

One example of the device 40 is shown in FIGS. 3A and 3B. It consists of a hollow cylindrical shape made of aluminum or other metal that is compatible with the process. Other materials, for example stainless-steel, Cu, or Ta, can be used. Alternatively, the device 40 can be made of SiC, alumina, or other dielectric material. Material thickness for the cylindrical embodiment of the device 40 that is shown in FIGS. 3A and 3B is 5 mm, but other thicknesses may be acceptable or preferred, depending on chamber and process parameters. For other practical reasons such as maximum temperature, thermal conductivity, rigidity, particle elimination, etc., thicknesses in the range of from 2 mm to 10 mm may be found appropriate, with surface texture or some other processed surface provided, as may be typically required for internal surfaces in sputtering systems known to persons skilled in this field. The dimensions of the plasma adjusting device 40 depend on actual chamber size and chamber aspect ratio. Typical dimensions of the plasma adjusting device 40 of the cylindrical type for a 300 mm wafer processing tool include a radius in the range of from 40 mm to 150 mm, preferably from 40 mm to 100 mm, and a height of from 10 mm to 150 mm, preferably from 10 mm to 80 mm, and more preferably of from 30 to 50 mm.

A typical geometrical shape for the device 40 is that of a hollow body in cylindrical form or of frusto-conical geometry having a bottom radius larger than the upper radius, as for example the device 30a illustrated in FIG. 7a. A hemispherical shape having a cross-section that is parabolic or of some other convex shape or combination of shapes is also useful. An example is the device 30b illustrated in FIG. 7B.

In applicant's U.S. patent application Ser. No. 10/854,607, filed May 26, 2004, hereby expressly incorporated by reference herein, a buffer device is disclosed which provides a complementary effect on the radial distribution of metal atoms and ions inside a processing chamber. With the present invention, devices are provided having shapes for buffering performance by improving plasma uniformity and radial plasma density control.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of providing uniformity in processing semiconductor wafers, the method comprising:
providing at the center of an annular region in a processing space within the chamber a hollow body having an end open to the processing space;
supporting a semiconductor wafer on a support in the chamber on a support opposite the processing space from the hollow body and facing the processing space; and
inductively coupling RF energy from an antenna at an end of a processing chamber into a plasma in the annular region.

2. The method of claim 1 wherein:
the antenna is a ring-shaped antenna configured to inductively couple the RF energy through a dielectric portion of a chamber wall from outside of the processing chamber into the annular region in the processing space.

3. The method of claim 2 wherein:
the hollow body is configured to be mounted inside of the dielectric portion of the chamber wall in axial alignment with the ring-shaped antenna.

4. The method of claim 1 further comprising:
etching the semiconductor wafer with the plasma.

5. The method of claim 4 wherein:
the etching is performed with pressure in the chamber at less than 10 mTorr.

6. The method of claim 1 further comprising:
depositing on the semiconductor wafer with an iPVD process, metal ionized for deposition by the plasma.

7. The method of claim 6 wherein:
the iPVD process is performed with pressure in the chamber of at least 30 mTorr.

8. The method of claim 1 for providing etching uniformity in in situ combined deposition and etch processing on semiconductor wafers further comprising:
etching the semiconductor wafer with the plasma; and
depositing on the semiconductor wafer with an iPVD process, metal ionized for deposition by the plasma.

9. The method of claim 8 wherein:
the iPVD process is performed at a pressure sufficiently high to thermalize the plasma in the processing space;
the etching is performed at a pressure lower than that required to thermalize the plasma in the processing space; and
the iPVD process and the etching are performed sequentially with the pressure being switched between the iPVD process and the etching.

10. The method of claim 8 wherein:
the iPVD process and the etching are performed simultaneously.

11. The method of claim 8 wherein:
the iPVD process and the etching are performed simultaneously to produce no net deposition.

12. A plasma source for providing plasma uniformity in the processing of semiconductor wafers over a wide range of process parameters, the source comprising:
a ring-shaped antenna configured to inductively couple RF energy through a dielectric portion of a chamber wall from outside of a vacuum processing chamber into a processing space within the chamber;
a hollow body configured to be mounted inside of the dielectric portion of the chamber wall in axial alignment with the ring-shaped antenna, the hollow body having an open end facing the processing space.

13. The system of claim 12 wherein:
the hollow body has a generally cylindrical shape axially aligned with the ring-shaped antenna with the open end being circular.

14. The system of claim 12 wherein:
the hollow body has a generally cylindrical shape axially aligned with the ring-shaped antenna with the open end being circular.

15. A semiconductor wafer processing apparatus comprising:
a vacuum processing chamber enclosing a processing space;
a vacuum system operable to maintain vacuum processing pressure in the vacuum processing chamber;
a sputtering target in the chamber having a sputtering surface in communication with the processing space;
a high-density plasma source having an electrode configured to couple RF energy into a distributed region in the processing space;
a substrate support in the chamber facing the processing space;
a hollow body at the center of the distributed region and having an end open to the processing space;
the sputtering target, the plasma source, the hollow body, the processing space and the substrate support being aligned on an axis of the vacuum processing chamber; and
a controller operable to control a plasma process of a semiconductor wafer on the substrate support in the vacuum processing chamber.

16. The apparatus of claim 15 further comprising:
an ionized physical vapor deposition system wherein the controller is operable to:
control the vacuum system to maintain a vacuum processing pressure in the vacuum processing chamber that is sufficiently high to result in a thermalized plasma when produced in the processing space,
control the sputtering target so as to sputter coating material into the vacuum processing space, and
control the high-density plasma source to produce a high density thermalized plasma in the processing space; and
a plasma etching system wherein the controller is further operable to:
control the vacuum system to maintain a vacuum processing pressure in the vacuum processing chamber that is effective for etching and insufficiently high to result in a thermalized plasma when produced in a processing space,
control the sputtering target so there is no net deposition on the semiconductor wafer, and
control the high-density plasma source and the bias potential of the substrate support to effectively etch the substrate.

17. The apparatus of claim 16 wherein:
the controller is programmed to operate the deposition system and the etching system to simultaneously or sequentially coat and etch a substrate when in the processing chamber.

18. The apparatus of claim 15 further comprising:
the controller is operable to operate the apparatus to sequentially or simultaneously perform an iPVD process and an etching process on a semiconductor wafer on the support in the processing chamber.

19. The apparatus of claim 18 wherein:
the controller is programmed to operate the apparatus to perform the iPVD process at a pressure sufficiently high to thermalize a plasma in the processing space, and to operate the apparatus to perform the etch process at a lower pressure insufficiently high to thermalize the plasma in the processing space.

20. The apparatus of claim 15 wherein the electrode antenna is ring-shaped and situated at an end of the processing chamber configured to inductively couple RF energy into the processing space.
